(19) United States
(12) Patent Application Publication
(10) Pub. No.: US 2020/0203473 A1
(43) Pub. Date: Jun. 25, 2020

(54) SEMICONDUCTOR DEVICE AND METHOD FOR FORMING THE SAME

(71) Applicant: Taiwan Semiconductor Manufacturing Co., Ltd., Hsin-Chu (TW)

(72) Inventors: Chun-Li LIN, Hsinchu City (TW); Yi-Fang LI, Baoshan Township (TW); Chun-Sheng WU, Hsinchu City (TW); Po-Hsiung LEU, Lujhu Township (TW); Ding-I LIU, Hsinchu City (TW)

(73) Assignee: Taiwan Semiconductor Manufacturing Co., Ltd., Hsin-Chu (TW)

(21) Appl. No.: 16/725,969

(22) Filed: Dec. 23, 2019

Related U.S. Application Data
(62) Division of application No. 13/460,868, filed on May 1, 2012, now abandoned.

(51) Int. Cl. H01L 29/06; H01L 21/762

(52) U.S. Cl. CPC H01L 29/06; H01L 21/76232

(57) ABSTRACT

In order to prevent formation of voids in STI film, after a second buried insulating layer is filled and planarized, a high density cap is formed embedded in the center region of the second buried insulating layer of the STI trench. The high density cap shields and protects the weaker center region of the second buried insulating layer of the STI trench from the subsequent processing steps and prevents formation of voids in the second buried insulating layer.

### CROSS-REFERENCE TO RELATED APPLICATIONS

This application is a Divisional of co-pending U.S. patent application Ser. No. 13/460,868, filed on May 1, 2012, the entire contents of which are incorporated herein by reference.

### FIELD

This disclosure relates generally to a method of manufacturing an isolation layer in semiconductor devices, and more particularly, to a method of manufacturing a void-free shallow trench isolation layer.

### BACKGROUND

Shallow trench isolation (STI) method provides superior device isolation effect on highly integrated semiconductor devices. As the design rule for integrated circuit semiconductor devices has been reduced to sub-micron range, in addition to the circuit pattern widths being reduced, the trench width for forming the STI film has also been reduced. However, although the width of the trench is reduced, the depth of the trench remains same and this resulted in the trenches for STI structure having a higher aspect ratio and presents difficulties for completely filling the trench with silicon oxide film. These problems persist even as the industry is migrating from high aspect ratio process (HARP) to flowable gap-filling technology for the STI trench.

### BRIEF DESCRIPTION OF THE DRAWINGS

FIG. 1A-1F are schematic cross-sectional views of early stages of a method of manufacturing an STI film.

FIG. 1G is a schematic cross-sectional view of an STI film that was formed using a conventional method.

FIGS. 2A-2D are schematic cross-sectional views of an STI film being manufactured according to an embodiment of the present disclosure.

FIG. 3 is a schematic illustration of the top sides of STI films that were formed by a conventional method showing the formation of voids.

FIG. 4 is a schematic cross-sectional view of STI films that were formed by the method according to an embodiment of the present disclosure.

FIG. 5 is a schematic illustration of the top sides of STI films that were formed by the method according to an embodiment of the present disclosure.

FIGS. 6A and 6B show two halves of a flowchart illustrating the STI method according to the present disclosure.

The features shown in the above referenced schematic drawings are illustrated schematically and are not intended to be drawn to scale nor are they intended to be shown in precise positional relationship. Like reference numbers indicate like elements.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Shallow trench isolation (STI) method, that requires a narrower space and has a superior isolation effect than the older local oxidation of silicon (LOCOS) method, has been used for isolation of devices in highly integrated semiconductor integrated circuit devices.

A popular way of filling the narrow shallow trench in STI method is double filling the trench with an insulating material having a superior interlayer filling characteristics, such as undoped silicate glass (USG) or high density plasma (HDP) film.

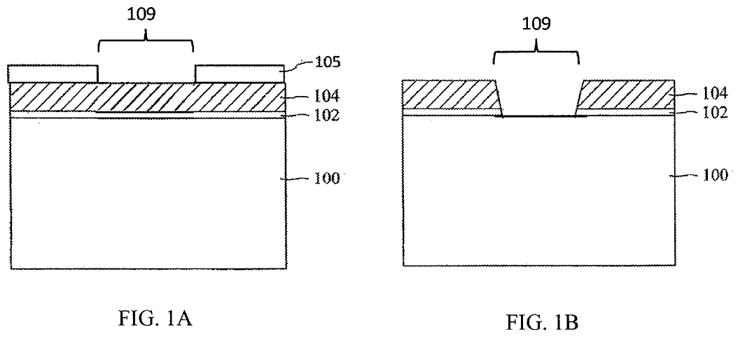

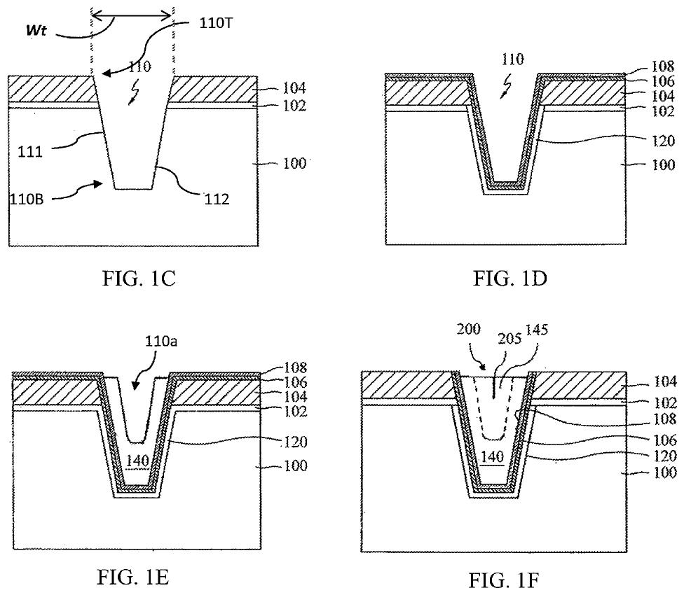

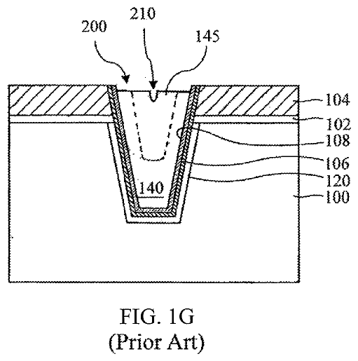

Referring to FIG. 1A, a pad oxide film 102 and a silicon nitride film 104 are sequentially deposited on a semiconductor substrate 100 such as a silicon substrate. The pad oxide film 102 can be formed by known techniques such as a thermal oxidation process, and the silicon nitride film 104 can be formed by known techniques such as a chemical vapor deposition (CVD) process.

In order to form the isolation trench, an isolation region 109 of devices is defined on the silicon nitride film 104 using a photo-resist pattern 105. Then, the pad oxide film 102 and the silicon nitride film 104 are dry etched using the photo-resist pattern as a mask and the semiconductor substrate 100 is exposed in the isolation region 109 as shown in FIG. 1B.

Referring to FIG. 1C, the photo-resist pattern 105 is then removed and a trench structure 110 with a predetermined depth is formed by dry etching the exposed semiconductor substrate 100 using the patterned silicon nitride film 104 and the pad oxide film 102 as masks. The width Wt of the resulting trench 110 is generally wider at the top of the semiconductor substrate 100 and becomes narrower towards the bottom of the trench because of a shortage of the etching gas.

Referring to FIG. 1D, a side wall oxide film 120 with a thickness in the range of about 20 to 100 Å is formed on the inner walls of the trench 110 by known techniques such as thermal oxidation. The side wall oxide film 120 is provided for rounding the corners of the trench 110. A liner 106 for buffering stress that could result from a difference in expansion coefficient between the side wall oxide film 120 and a buried insulating oxide film, which will be formed in the following process, is formed on the sidewall oxide film 120. The liner 106 can be formed of a silicon nitride film having a thickness in the range of about 50 to 100 Å. Alternatively, the liner 106 may be omitted. An oxide film such as a medium temperature oxide (“MTO”) film 108 having a thickness in the range of about 10-50 Å may be formed on the liner 106. The MTO film 108 can be deposited by known techniques such as a CVD process and is provided for protecting corners of the trench 110 from plasma damage which can occur when depositing an HDP film.

Referring to FIG. 1E, a first buried insulating oxide film 140, such as a USG film or a HDP film, is deposited on the MTO film 108 to a thickness enough to fill the trench 110 and then etched back, using a wet etch-back process for example, leaving only a portion of the first buried insulating oxide film 140 in the trench 110 as shown. After the etch-back process, the first buried insulating oxide film 140 is partially filling the trench and leaves a reduced trench opening 110a as shown in FIG. 1E.

The wet etch-back process is performed by, for example, dipping the semiconductor substrate 100 having the first buried insulating oxide film 140 in a mixture of a LAL solution and a SCl solution for a predetermined time. Although the dipping method has been used for etching back of the first buried insulating oxide film 140, one of ordinary skill in the art will appreciate that other methods can also be used to etch back the first buried insulating oxide film.

Next, a second buried insulating oxide film 145 is deposited over the structure covering the first buried insulating oxide film 140 to a thickness that is enough to fill the reduced trench opening 110a. The second buried insulating oxide film 145 can be formed of, for example, a USG film or an HDP film. Next, the second buried insulating oxide film 145 is planarized until the MTO film 108 and the liner 106 surrounding the trench 110 are removed and the surface of the silicon nitride film 104 is exposed. The planarization process may be performed by a CMP process. The resulting STI oxide film 200 is shown in FIG. 1F. However, because of the sloped angle of the trench side walls, as the second buried insulating oxide film 145 fills the reduced trench opening 110a by growing from sidewalls towards the center of the trench, the filling process often leaves a seam 205 near the top surface of the central region of the STI oxide film 200.

Referring to FIG. 1G, during subsequent processing, the seam 205 can develop into a void 210. During a hydrofluoric acid (“HF”) solution dip process steps that follow the STI process, such as nitride removal, the HF will etch into the seam 205 and the resulting loss of the oxide material enlarges the seam into the void 210. Therefore, the central region of the STI oxide film 200 containing the seam 205 is referred to herein as the “undesired portion.”

FIG. 3 shows an SEM micrograph showing the top surfaces of STI oxide films where a void 210 is identified. Such voids are not desired because, the conductive material for forming a gate electrode can fill the void 210 and can cause bridging effect, i.e., unwanted electrical connection between adjacent gates.

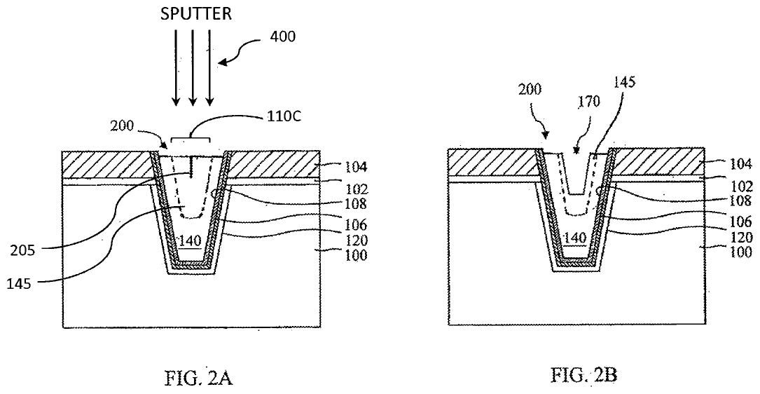

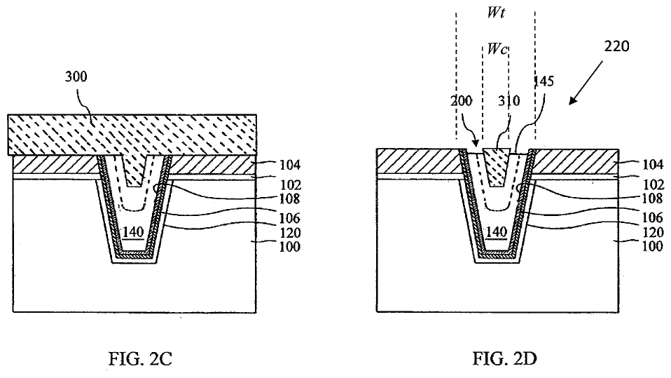

Referring to FIGS. 2A-2D, a process according to an embodiment of the present disclosure will now be described. Referring to FIG. 2A, after the second buried insulating oxide film 145 is planarized, the undesired portion of the second buried insulting film 145, i.e., the seam 205 and the immediate surrounding area is removed. A high density plasma (HDP) sputtering process can be used for this removal process. The primary particles 400 for the sputtering process can be supplied in a number of ways, for example by a plasma, an ion source, an accelerator or by a radioactive material emitting alpha particles. Referring to FIG. 2B, the sputtering forms a cap opening 170 in the second buried insulating oxide film 145. Because the etching process of sputtering is weaker further away from the sputtering source, the cap opening 170 retains a cross-sectional shape of an inverted trapezoid form as shown.

Referring to FIG. 2C, next, a layer of high density oxide material 300 is deposited on the second buried insulating oxide film 145 filling the cap opening 170 at the center region of the STI trench where the seam 205 used to be with the high density oxide material. The high density oxide material 300 can be PECVD undoped silicate glass or high density plasma (HDP) undoped silicate glass depending on the integration needs of the semiconductor device. The high density cap material could be SiH₄-based or tetraethyl orthosilicate (TEOS)-based depending on the STI process.

Next, excess high density cap material 300 is removed by a planarization process, such as chemical mechanical polishing (CMP), leaving behind a high density cap 310 in the center of the STI oxide film 200 as shown in FIG. 2D. The thickness of the high density cap material 300 deposited can be adjusted to obtain the desired thickness for the high density cap 310 as necessary to meet the particular STI process needs.

The high density cap 310 replaces the seam 205 in the STI oxide film 200 and acts as a shield protecting the STI oxide film 200 from the subsequent processes mentioned above and prevents formation of the voids 210. The width Wc of the high density cap 310 is about half of the trench width Wt. In one embodiment Wc is at least half of Wt.

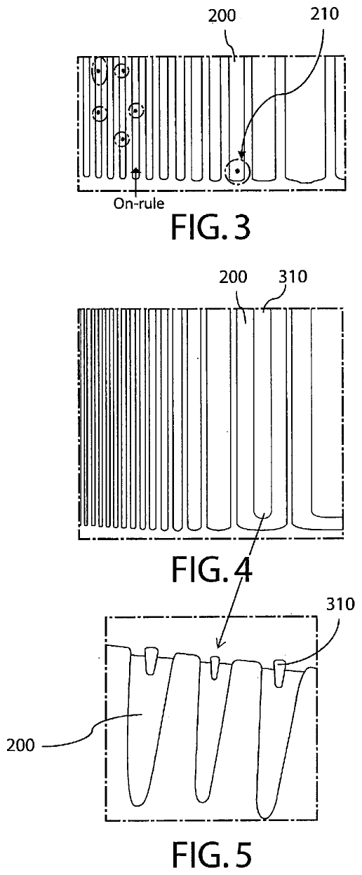

FIG. 4 is a cross-sectional micrograph of STI oxide films 200 that were manufactured according to an embodiment of the process of the present disclosure. The high density caps 310 are identified. FIG. 5 shows an SEM micrograph showing the top surfaces of STI oxide films 200 that were manufactured according to the process of this disclosure in which the high density caps 310 are identified.

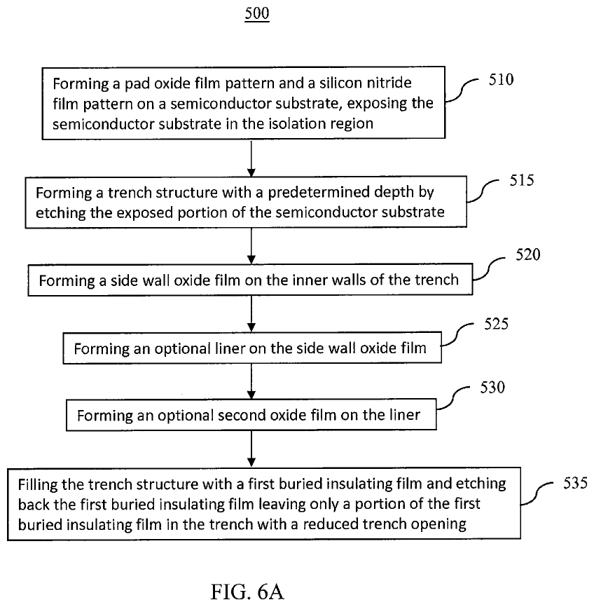

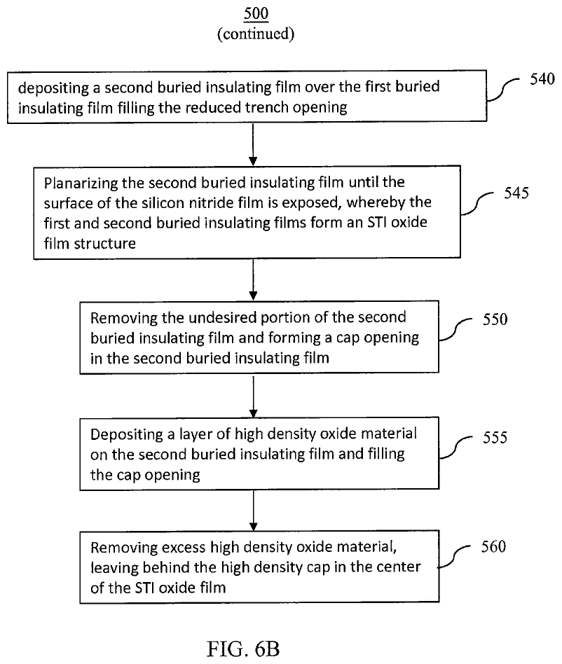

FIGS. 6A and 6B together show a flowchart 500 for the process according to the present disclosure. At box 510, a pad oxide film pattern and a silicon nitride film pattern are formed on a semiconductor substrate, such as a silicon substrate, where the nitride film pattern defines an isolation region and exposing the semiconductor substrate in the isolation region. At box 515, the exposed portion of the semiconductor substrate is dry etched to form a trench structure with a predetermined depth. At box 520, a side wall oxide film with a thickness in the range of about 20 to 100 Å is formed on the inner walls of the trench by known techniques such as thermal oxidation. The side wall oxide film is provided for rounding the corners of the trench. At box 525, an optional liner for buffering the stress that could result from a difference in expansion coefficient between the side wall oxide film and a buried insulating oxide film, which will be formed in the subsequent process, is formed on the sidewall oxide film. At box 530, an oxide film such as an MTO film having a thickness in the range of about 10-50 Å may be formed on the liner (or on the side wall oxide film where the liner is not used). At box 535, a first buried insulating oxide film, such as a USG film or a HDP film, is deposited on the MTO film to a thickness enough to fill the trench and then etched back, leaving only a portion of the first buried insulating oxide film in the trench, where the first buried insulating oxide film is partially filling the trench and forming a reduced trench opening. At box 540, a second buried insulating oxide film is deposited over the resulting structure covering the first buried insulating oxide film and filling the reduced trench opening. At box 545, the second buried insulating oxide film is planarized until the MTO film and the liner surrounding the trench are removed and the surface of the silicon nitride film is exposed, whereby the first and second buried insulating oxide films form an STI oxide film structure. At this point, the undesired portion of the STI oxide film structure generally contains a seam formed by the second buried insulting film material. At box 550, the top surface of the second buried insulating oxide film is sputtered, removing the undesired portion of the second buried insulating oxide film and forming a cap opening in the second buried insulating oxide film. At box 555, a layer of high density oxide material is deposited on the second buried insulating oxide film filling the cap opening. The cap opening filled with the high density oxide material forms a high density cap. At box 560, excess high density cap material is removed by a planarization process, such as chemical mechanical polishing (CMP), leaving behind the high density cap in the center of the STI oxide film. As mentioned previously above, the high density cap protects the STI oxide film structure from subsequent wet processes that can etch the STI oxide film.

Referring to FIGS. 1C, 2A and 2D, the STI structure 220 comprises a semiconductor substrate 100, a trench 110 having a top portion 110T and a bottom portion 110B, the trench being defined by a first sidewall 111 and a second sidewall 112 opposite the first sidewall, the first and second sidewalls extending from the top portion 110T down to the bottom portion 110B of the trench 110, wherein the trench is widest at the top portion 110T, having a width Wt and narrowest at the bottom portion 110B. A first buried insulating oxide film material 140 is deposited in the trench and a second buried insulating oxide film material 145 is deposited on the first buried insulating oxide film material 140, whereby the first and second buried insulating oxide film materials fill the trench 110 and the second buried insulating oxide film material forms a central portion 110C of the STI structure at the top portion 110T of the trench. The STI structure 220 further comprises a high density cap 310 formed and embedded in the second buried insulating oxide film 145 at the top portion 110T that protects the second buried insulating oxide film 145 from subsequent downstream processes, such as HF dip.

Although the subject matter has been described in terms of exemplary embodiments, it is not limited thereto. Rather, the appended claims should be construed broadly, to include other variants and embodiments, which may be made by those skilled in the art.

1. A shallow trench isolation structure comprising:
a semiconductor substrate;
a trench having a top portion and a bottom portion, the trench being defined by a first sidewall and a second sidewall opposite the first sidewall, the first and second sidewalls extending from the top portion down to the bottom portion of the trench, wherein the trench is widest at the top portion, having a width Wt and narrowest at the bottom portion;
a first buried insulating oxide film material deposited in the trench;
a second buried insulating oxide film material deposited on the first buried insulating oxide film material, whereby the first and second buried insulating oxide film materials filling the trench and the second buried insulating oxide film material forming a central portion of the shallow trench isolation structure at the top portion; and
a high density cap formed and embedded in the second buried insulating oxide film at the top portion.

2. The structure of claim 1, wherein the high density cap has a width Wc that is half of Wt.

3. The structure of claim 1, wherein the high density cap has a width Wc that is at least half of Wt.

4. The structure of claim 1, wherein the high density cap is PECVD undoped silicate glass.

5. The structure of claim 1, wherein the high density cap is plasma undoped silicate glass.

6. The structure of claim 1, wherein the high density cap is SiH₄-based oxide material.

7. The structure of claim 1, wherein the high density cap is TEOS-based oxide material.
